(19) United States
(12) Patent Application Publication
(10) Pub. No.: US 2019/0241428 A1
(43) Pub. Date: Aug. 8, 2019

(54) SPACE-EFFICIENT PLANAR INTERPOSER FOR ENVIRONMENT-RESISTANT PACKAGING

(71) Applicant: ePack, Inc., Ann Arbor, MI (US)

(72) Inventors: Jay MITCHELL, Ann Arbor, MI (US); David LEMMERHIRT, Ann Arbor, MI (US); Onnop SRIVANNAVIT, Ann Arbor, MI (US)

(21) Appl. No.: 16/268,636

(22) Filed: Feb. 6, 2019

Related U.S. Application Data
(60) Provisional application No. 62/626,767, filed on Feb. 6, 2018.

(51) Int. Cl. B81B 7/00

(52) U.S. Cl. CPC B81B 7/0058

(57) ABSTRACT

A space-efficient, planar interposer for packaging and support of a device (e.g., MEMS device) is provided. The interposer has a device-mounting region for supporting a device, such as a sensor, accelerometer, gyroscope, etc. The interposer is formed from a single layer of material, and has cut-outs or gaps formed therein to define springs. The springs connect the device-mounting region to anchor regions configured to anchor the interposer to an underlying substrate or package. The cut-outs or gaps of the interposer are made with space-efficiency in mind. In certain embodiments, the cut-outs or gaps extend inwardly toward the center of the interposer such that the anchor regions can also extend inwardly, and at least a portion of each anchor region is further inboard on the interposer than a portion of the device-mounting region. As such, the anchor regions can be located within an extended or virtual perimeter of the device-mounting region.

### CROSS-REFERENCE TO RELATED APPLICATIONS

This application claims the benefit of U.S. provisional application Ser. No. 62/626,767 filed Feb. 6, 2018, the disclosure of which is hereby incorporated in its entirety by reference herein.

### TECHNICAL FIELD

This disclosure relates generally to the field of electronic packaging, and more specifically to interposer devices that can be used within electronic packages to mitigate adverse performance effects of mechanical stress, vibration, and temperature variation on packaged inertial sensors. It can also be applied to crystal or MEMS-based oscillators, pressure transducers, optical sensors, magnetometers or other electronic components whose performance is degraded by stress, vibration, or temperature variation.

### BACKGROUND

In recent years, inertial sensors manufactured using microelectromechanical systems (MEMS) technology have become pervasive in applications ranging from consumer electronics (e.g. cellular phones, video game controllers, virtual reality headsets) to high-performance military applications (e.g. avionics, inertial guidance for missiles, pointing devices for weapons). The inherent stability and resolution of these sensors has vastly improved and now rivals that of much larger conventional mechanical and optical sensors. However, the performance of MEMS inertial sensors is dramatically degraded by environmental factors such as temperature and humidity variation, vibration, and mechanical stress coupled to the devices from the outside world. The susceptibility of sensors to these factors is highly dependent on how the sensor is packaged at the die level and how it is integrated into system electronics and housings. Furthermore, device packaging can impact how multiple sensors within a system or subsystem interact with one another (e.g. mechanical and electrical crosstalk).

Typical approaches to isolating MEMS sensors from deleterious environmental factors have focused on system-level macro-scale isolation mechanisms. For example, to isolate a sensor from excessive vibration, the sensor may be incorporated into a heavy housing with elastomeric vibration isolators. To reduce the impact of temperature variations on a sensor, the device may be surrounded by thermally insulating material and/or integrated with an active system-level heating or cooling system. A rigid metallic mounting structure can be used to make sensors less susceptible to mechanical stress from thermal expansion of printed circuit boards or other system components. These approaches typically require a substantial increase in system size, weight, power consumption and cost.

Several prior art approaches incorporate an isolation structure directly within a device package to reduce translation of mechanical forces from the package to the sensor. This has the advantage of isolating the sensor from stress induced by thermal-expansion of the package itself and from stress induced on the package by printed circuit boards or other outside system components. Prior art isolation structures include compliant tabs built into ceramic chip carrier packages and compliant interposers installed between the sensor and the package floor. One example mounts a sensor on a central base region supported by compliant springs extending from the base region. A disadvantage of these prior art approaches is that springs extend outward from the base region, consuming substantial area outside the base region. In addition, prior art approaches use mounting structures on each of the four sides of the interposer, which provides stable mechanical mounting, but requires four space-consuming spring structures. Another prior art approach uses multiple stacked substrates to accomplish stress isolation between a package substrate and a sensor die, which necessitates a taller stack height and increased assembly complexity.

### OBJECTS OF THE DISCLOSURE

One object of this disclosure is to provide an in-package isolation structure consisting of an interposer that can be inserted between a device and a device package.

A further object of this disclosure is to isolate a device such as a sensor from mechanical stress that can be caused by thermal expansion mismatches between the sensor and the sensor package or between the sensor packaging and the underlying circuit board or substrate.

A further object of this disclosure is to filter and attenuate vibrations, either to prevent vibration arising from the sensor from coupling to other devices in the system or to protect the sensor from undesired vibrations that could enter from the environment or neighboring devices.

A further object of this disclosure is to stabilize the temperature of a device in order to reduce or eliminate changes in the device sensitivity, offset, or other parameter which can arise directly from changes in temperature or indirectly from mechanical stress induced by temperature changes in the environment or within the system.

A further object of this disclosure is to thermally isolate a device from the rest of the system and from the environment in order to minimize the power needed to heat or cool the device.

A further object of this disclosure is to provide the isolation features above while not substantially adding to the size of the device package.

A further object of this disclosure is to provide the isolation features above using a component that is compatible with assembly processes commonly used for packaging semiconductors (e.g pick-and-place assembly, wire-bonding, adhesive or metal die-attach).

To meet these and other objectives, this disclosure contemplates a planar interposer that can be installed between a sensor or other device and an underlying substrate or package. The interposer can have a die-mounting region supported by compliant springs that terminate in anchor regions, with the geometry of the die-mounting region, springs, and anchor regions defined in such a way as to minimize the lateral dimensions of the interposer.

Stress isolation and vibration filtering is accomplished by designing legs that act as springs, which, when combined with the mass of the device and the dampening of surrounding gas or fluid (if any), produces a mass-spring-damper system that filters unwanted vibrations from coupling between the device and the underlying substrate. The springs may be structured with wrap-around perpendicular members with approximately the same length in both dimensions; this L-shape provides approximately equal spring constants in each dimension, providing symmetric stress and vibration isolation to the device on the interposer.

In one embodiment, temperature stabilization of the device is accomplished by including on the interposer a thin-film heating element that delivers heat to the device via one or more of solid conduction, gas conduction, convection, and radiation. To reduce the amount of power required to heat the device, the springs are designed to be long and narrow for reduced thermal conductivity. In addition, the interposer, in one embodiment, is made from a material with a low thermal conductivity, such as glass. In another embodiment, where heat sinking the device on the platform is desired, the interposer can be made from a material with a high thermal conductivity, such as silicon or metal.

The interposer can be made of a material with a coefficient of thermal expansion that is approximately equal to the that of the substrate of the device, so that stress is not induced on device when the temperature changes. For example, for a silicon device substrate, the interposer can be made from silicon or from a glass with a similar coefficient of thermal expansion to silicon.

To promote space-efficiency while enabling the features above, the die mounting region of the interposer can be shaped with cut-out regions for the legs and anchors to fit within. This allows the interposer to be very compact, with outside dimensions ideally not much larger than the device die itself. In addition, the anchor regions may be spread out along two axes, allowing for stable mounting of the interposer with only two legs. The anchor regions may be affixed to an underlying package or substrate with two or more epoxy dots, metal stud bumps, or solder balls, providing four-point stable mounting without the need for four individual legs.

### BRIEF DESCRIPTION

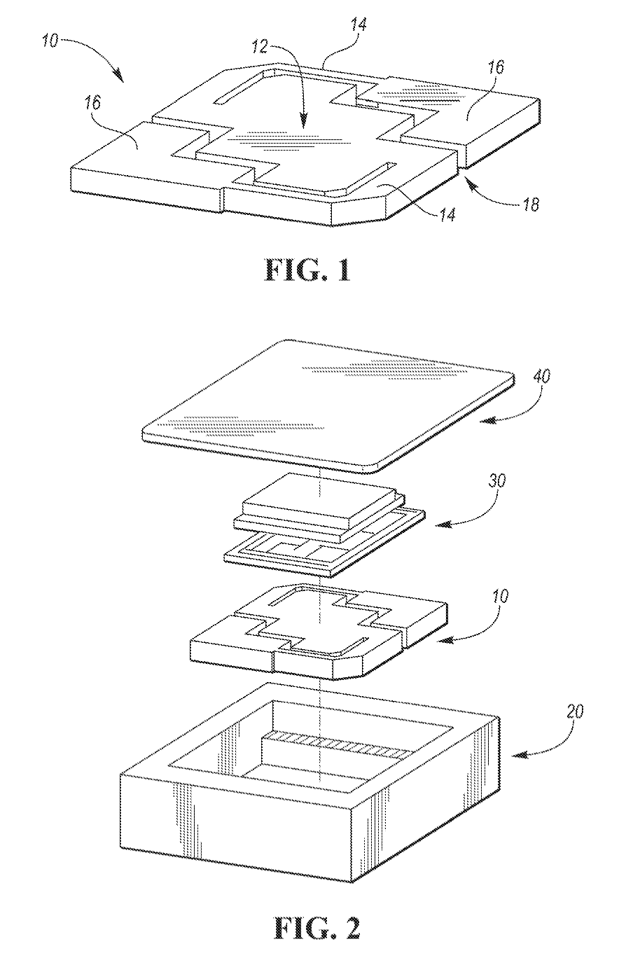

FIG. 1 is a front perspective view of an interposer platform, according to one embodiment.

FIG. 2 is an exploded perspective view of a package assembly for a device using a planar interposer platform between the device being packaged and the underlying package, according to one embodiment.

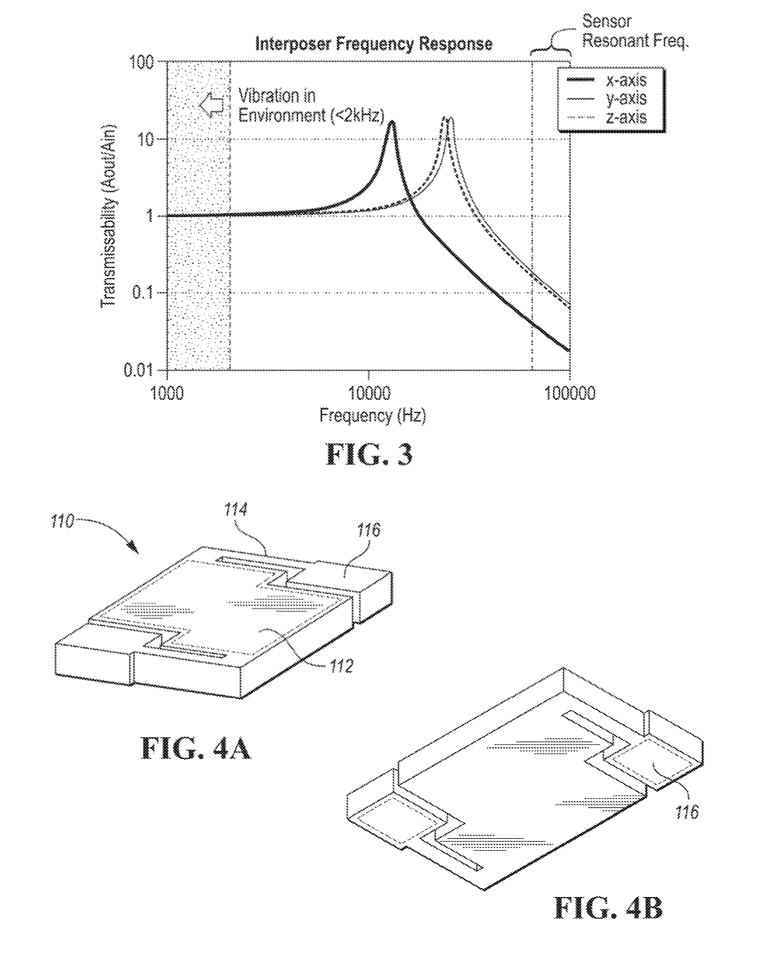

FIG. 3 is a graphical illustration of frequency responses of an interposer platform designed for vibration filtering, according to one embodiment.

FIG. 4A is a top perspective view and FIG. 4B is a bottom perspective view of the interposer platform, according to one embodiment.

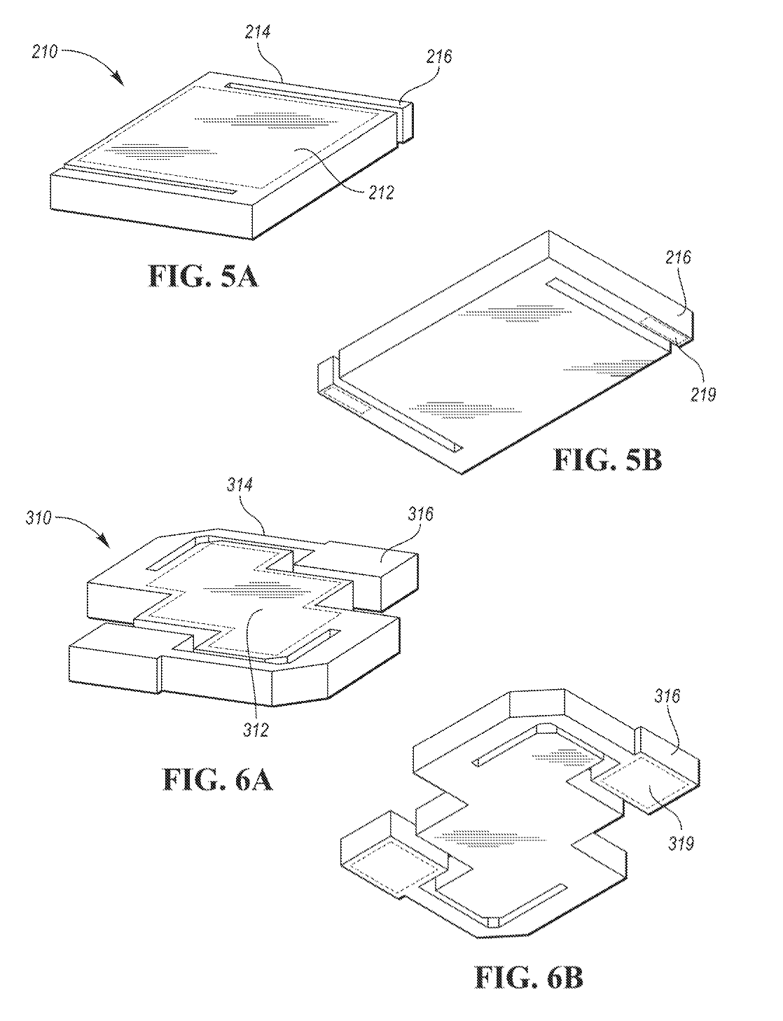

FIG. 5A is a top perspective view and FIG. 5B is a bottom perspective view of an interposer platform according to a second embodiment.

FIG. 6A is a top perspective view and FIG. 6B is a bottom perspective view of an interposer platform according to a third embodiment.

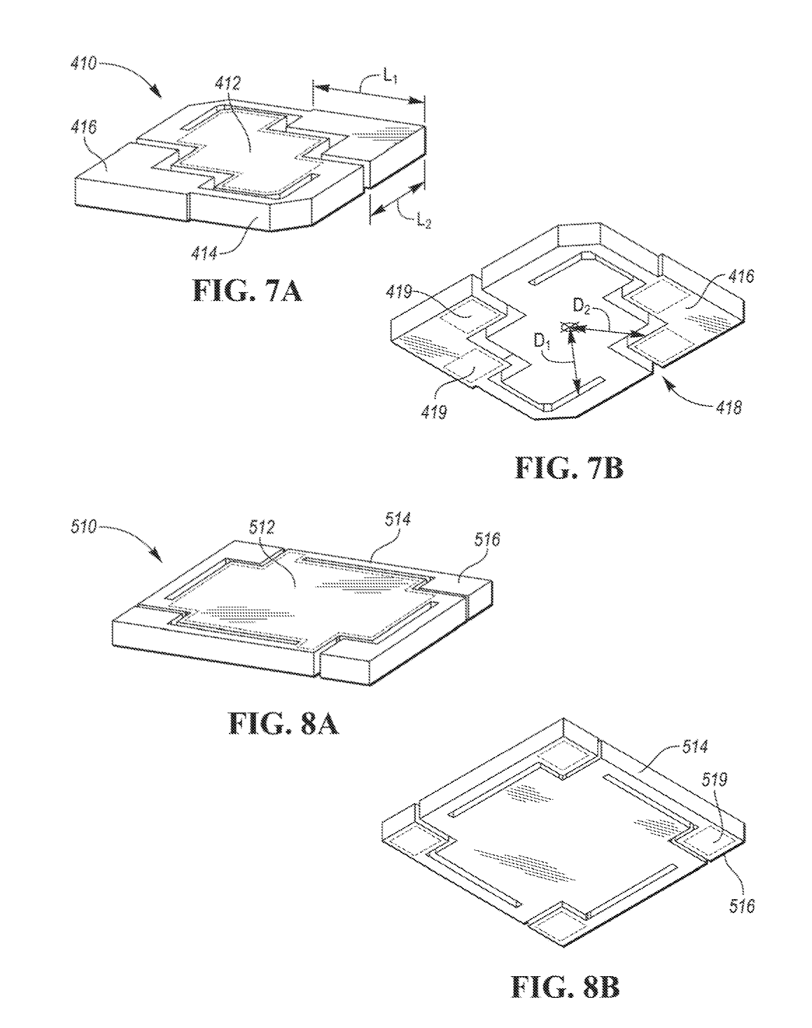

FIG. 7A is a top perspective view and FIG. 7B is a bottom perspective view of an interposer platform according to a fourth embodiment.

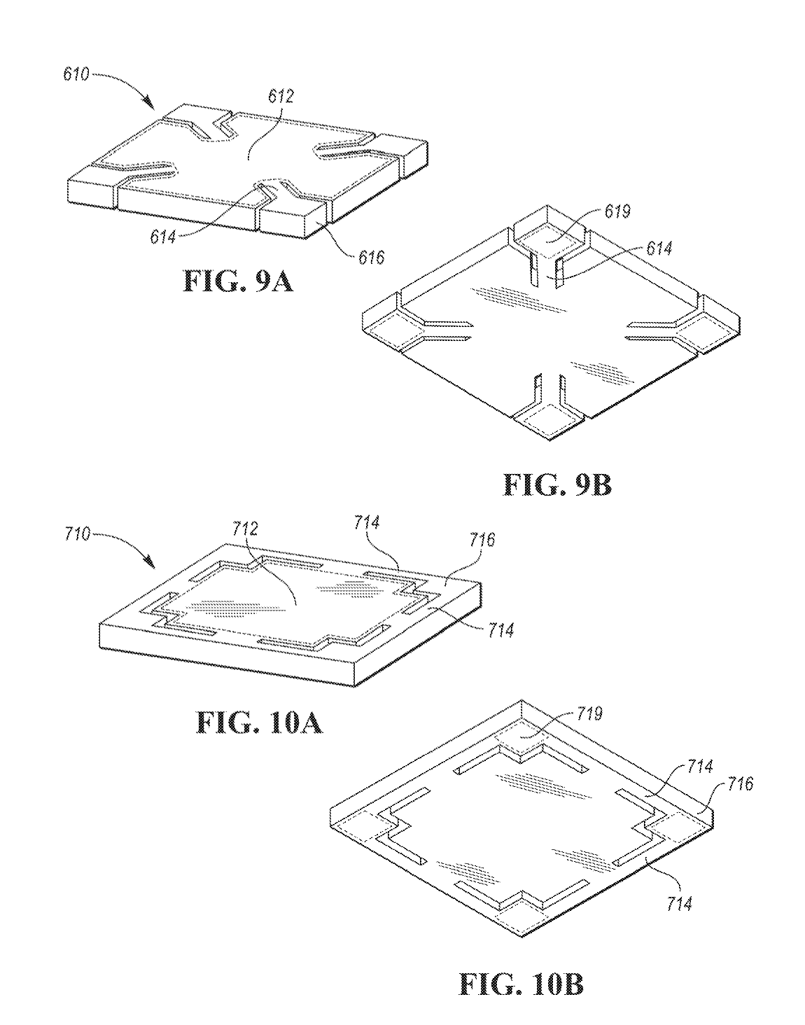

FIG. 8A is a top perspective view and FIG. 8B is a bottom perspective view of an interposer platform according to a fifth embodiment.

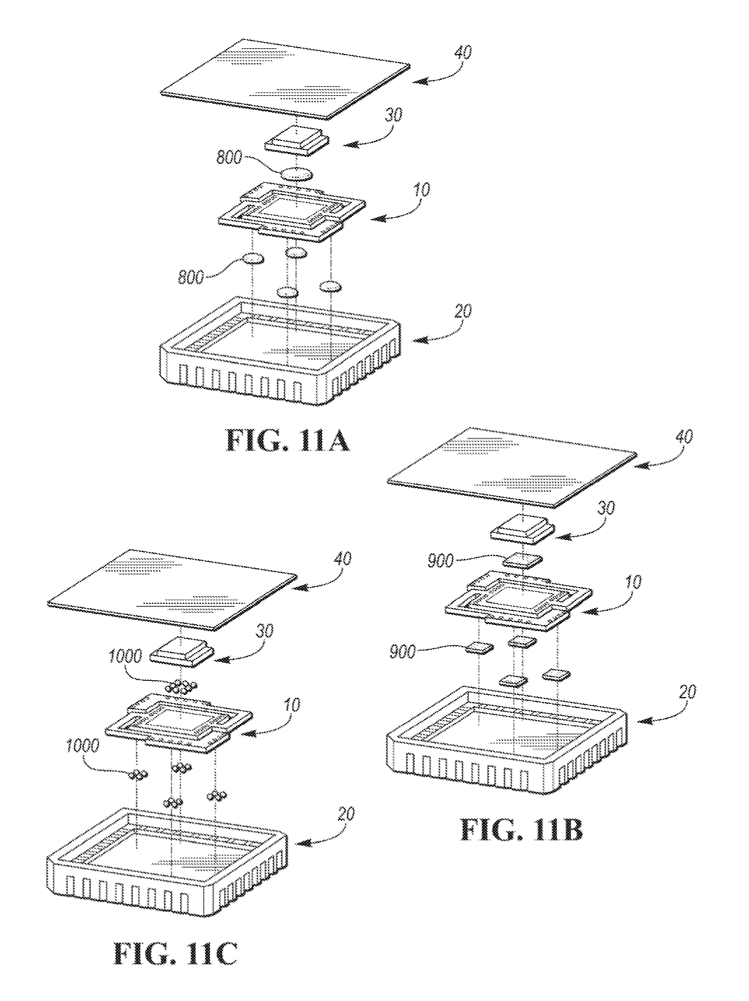

FIG. 9A is a top perspective view and FIG. 9B is a bottom perspective view of an interposer platform according to a sixth embodiment.

FIG. 10A is a top perspective view and FIG. 10B is a bottom perspective view of an interposer platform according to a seventh embodiment.

FIG. 11A-11C are exploded perspective views of a package assembly for a device using a planar interposer platform between the device being packaged and the underlying package, according to embodiments in which FIG. 11A utilizes adhesive (e.g., epoxy) dots with curing for anchor mounting and die attachment, FIG. 11B utilizes solder preforms for anchor mounting and die attachment, and FIG. 11C utilizes metal stud bumps with thermocompression or thermosonic bonding for anchor mounting and die attachment.

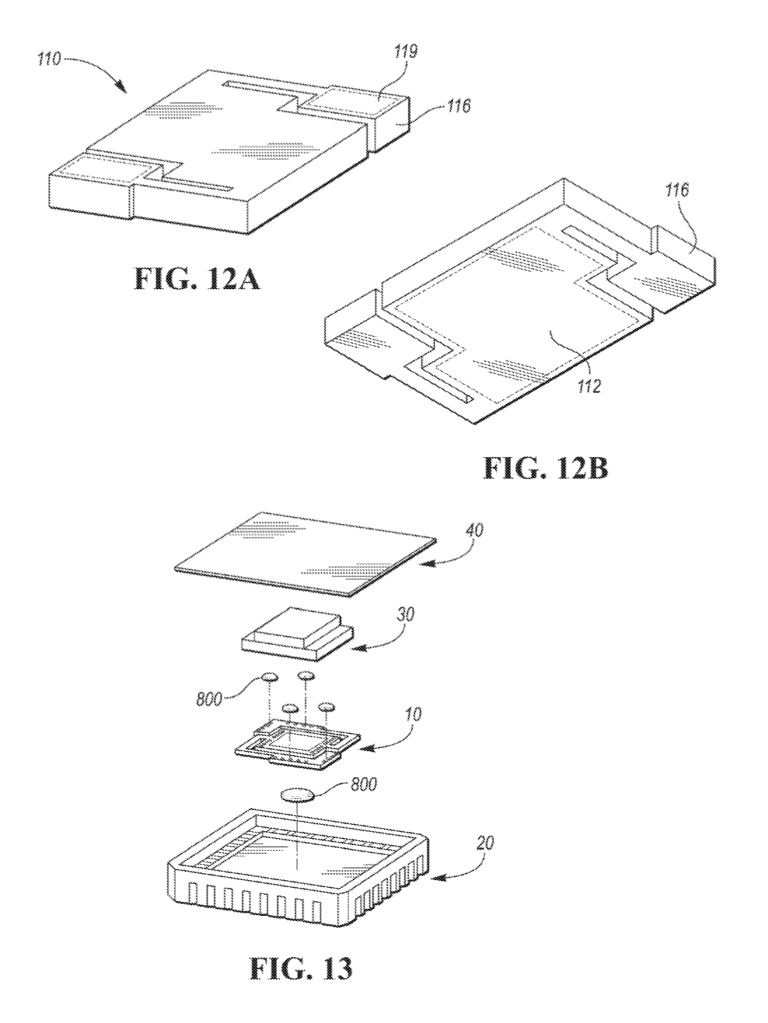

FIG. 12A is a top perspective view and FIG. 12B is a bottom perspective view of an interposer platform according to an embodiment configured to “inside-out” mounting.

FIG. 13 is an exploded perspective view of a package assembly for a device with one mounting option according to an embodiment.

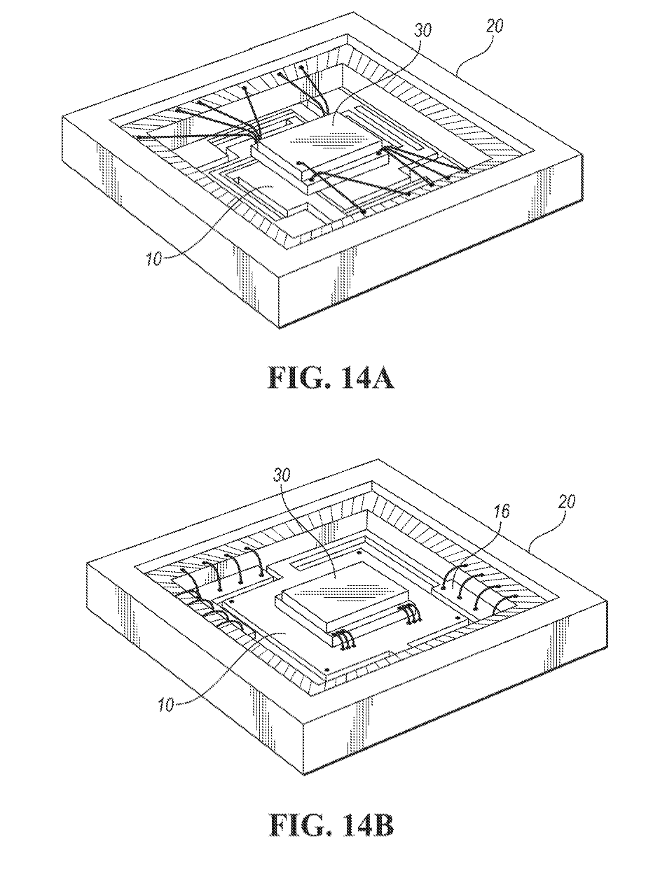

FIG. 14A is a top perspective view of a device mounted on an interposer platform with electrical connections established by wire-bonding directly from the device to pads on the package or underlying substrate, according to one embodiment. FIG. 14B is a top perspective view of a device mounted on an interposer platform with electrical connections established by wire-bonding from the device to pads patterned on the interposer mounting region, according to one embodiment.

### DETAILED DESCRIPTION

Various embodiments of this disclosure include a planar interposer platform (which can also be referred as a platform or suspension platform or isolation substrate) that accomplishes stress isolation and vibration filtering by suspending a “mounting region” from compliant legs machined into the same single substrate layer as the mounting region. FIG. 1 illustrates one embodiment of an interposer (also referred to as interposer platform) 10 and its primary features, including a mounting region 12 (e.g., device-mounting region configured to support a device) at its central region, a pair of legs 14 that connect the mounting region 12 to a pair of corresponding anchors 16. The legs 14 can be formed by removing material from cutout regions 18. The legs 14 act as springs to support the mounting region 12 where a device will be mounted. The L-shape of the springs provide similar compliance along all three axes (X, Y, and Z). The anchor regions 16 cover a spread-out area for stable attachment to an underlying substrate.

FIG. 2 shows how the interposer is assembled into a package, according to an embodiment. In particular, the assembly includes a package 20 having an underlying substrate, the interposer platform 10, a device 30 that is being packaged, and a packaged lid 40. The design features of the interposer allow it to be used without increasing the lateral dimensions of the package that would be used without the interposer. In some embodiments, the interposer can be designed to fit fully beneath the device being packaged. The features of this interposer platform are described below.

### I. Interposer Geometric Design

A. Geometric Features

1. Legs/Springs.

The interposer has compliant legs 14 that are machined into a single-layer substrate from which the interposer is formed by removing material in the cutout regions 18. The legs of the interposer function as compliant springs supporting the mounting region. The shape and dimensions of the legs can be designed to target desired features such as stress isolation, vibration filtering, thermal isolation, and space efficiency, as described below:

a. Stress Isolation.

The compliant interposer legs, acting as springs, can isolate the device on the interposer from system-level mechanical stress applied to the package in which it is installed, for example from thermal expansion of an underlying printed circuit board, residual stress in solder joints relaxing over time, or stress coupled in from mounting a system in a housing. As few as two legs can be used, with connections to the mounting region positioned approximately radially symmetric about the center of mass of the mounting region. Using a small number of legs increases compliance and consumes less space—so, for example, two legs may be preferred compared to four legs.

b. Vibration Filtering.

The compliant interposer legs, acting as springs, form a spring-mass-damper system when combined with the mass of the interposer mounting region, the device mounted, the mounting materials, and the gas or fluid surrounding the platform in the package. The properties of the springs and other components in the spring-mass-damper system can be designed to achieve a specified frequency response, enabling the interposer-based package to deliver vibration filtering as illustrated in FIG. 3. FIG. 3 provides an illustration of the frequency response of an interposer platform designed for vibration filtering, showing the resonant peaks along three axes for the spring-mass-damper system formed by the interposer and other components in the system. The interposer springs (legs) can be designed to filter out vibration in the frequency range near the resonant frequency of a sensor or other device being isolated on the platform. The springs are also designed to avoid resonant peaks of the interposer structure falling in the range of environmental vibration (e.g. from a vehicle) so that these modes are not excited during normal operation. Vibration filtering can be used to isolate the device on the interposer from vibrations in the outside world that can be coupled to the device through the package and mounting materials. Similarly, vibration filtering can prevent vibrations produced by the device itself from coupling outward to neighboring devices in the system. This, for example, can be used to prevent coupling between neighboring devices in a multi-sensor/actuator system (e.g. a system with multiple resonating MEMS gyroscope structures). The springs can have L-shaped or similar geometry to provide a spring constant that is approximately equal in all three orthogonal axes.

c. Thermal Isolation.

The geometry and material properties of the legs can be designed to achieve desirable thermal conduction properties. Long narrow legs, especially when made from a thermally-insulating material such as glass, form a high-thermal-resistance path between the mounting region and the anchors and underlying substrate or package, achieving a high thermal impedance between the device being insulated and the environment. By contrast, shorter, wider legs reduce the thermal impedance for applications that require heat-sinking of the device on the platform.

2. Anchors.

Each leg of the interposer terminates in an individual anchor that extends over a large lateral area to promote stability and avoid rocking. Each anchor should include at least one mounting point (see FIG. 4) but can preferably include two or more mounting points that are spread out for stability. (See FIG. 7.) For example, two dots of epoxy or other adhesive can be used to bond each anchor to the underlying package or substrate at each of these mounting points. In this way, even with only two legs, the overall platform will be supported stably at four or more locations, like a table. This makes the interposer platform more stable during operation and less prone to tilting during assembly. Alternatively, as illustrated in FIG. 5, the interposer can be anchored to the underlying package using two or more spaced-out points along an anchor region that is the same width as the leg/spring itself. This allows the overall dimensions of the interposer to remain compact while maximizing the size of the central mounting region.

3. Mounting Region.

The mounting region of the interposer is shaped to provide an area to affix a device (such as an integrated circuit, MEMS sensor, or stack of chips) while minimizing the overall outside dimensions of the interposer. This can be accomplished by using a shape with “cutouts” to allow space for the anchors or legs to extend into the mounting region, under the mounted device, to save area. This allows the device to be mounted in a package size similar or identical to that which would be used for the device without the interposer. The device being isolated can be affixed the mounting region using adhesive, solder preforms, metal stud bumps, or any other die-attach method.

B. Example Embodiments of Space-Efficient Interposer Geometry

The geometric design features described above (legs, anchors, and mounting region) can be combined in numerous ways to achieve space-efficient planar interposers. The examples below embody different combinations of the geometric design features, which deliver different performance and size advantages. In these various embodiments, like (but varying) structure is illustrated by reference numbers that increase by 100.

### 1. First Embodiment

See FIGS. 4A-4B. An interposer platform 110 with two narrow flexible legs (springs) 114 supporting a central device-mounting region 112 where a device to be isolated can be affixed. Each leg terminates in a respective anchor 116 that provides area for one or more mounting points on its underside to attach the interposer to an underlying package or substrate. The mounting region 112 has cutout regions 118 into which the anchors extend, allowing the interposer to maintain a compact footprint with a simple rectangular geometry. In this and all embodiments, the broken lines in the mounting region may be mounting points where adhesive is located. As can be seen, the adhesive may cover a majority of the anchor region 112, and the increased width of the anchor region 112 relative to the springs 114 allows for a larger surface area of adhesive to be provided, increasing the stability of the interposer. The interposer 110 can optionally be designed such that the entire interposer fits beneath the device being mounted.

### 2. Second Embodiment

See FIGS. 5A-5B. An interposer platform 210, similar to the first embodiment, but with anchor areas 216 integrated within the legs 214 themselves without widened anchor regions. In this case the cutout 218 regions are just large enough to accommodate the width of the narrow legs since no additional cutout is needed to accommodate larger anchors. The legs 214 can extend linearly along a linear edge of the device-mounting region 212. Mounting points 219 can be spaced out along the legs 214 to provide mounting with the package and greater stability. The elimination of widened anchor regions allows the interposer to maintain a compact footprint with a simple rectangular or square geometry. The interposer can optionally be designed such that the entire interposer fits beneath the device being mounted.

### 3. Third Embodiment

See FIGS. 6A-6B. An interposer platform 310, similar to the first embodiment, but with L-shaped springs or legs 314 that promote equivalent mechanical compliance along three orthogonal axes. This concept could be extended to include platforms with more than two L-shaped springs, for example, three, four, five, or more L-shaped legs. Each leg 314 terminates in an individual anchor 316 that provides area for one or more mounting points to attach the interposer to an underlying package or substrate. The device-mounting region 312 has cutout regions 318 into which the anchors extend, allowing the interposer to maintain a compact footprint with a simple rectangular geometry. Package-mounting points 319 are provided on the underside of the anchors 316. The interposer can optionally be designed such that the entire interposer fits beneath the device being mounted.

### 4. Fourth Embodiment

See FIGS. 7A-7B. An interposer platform 410, similar to the third embodiment, having L-shaped springs or legs 414, but with larger anchor regions 416 extending along two axes. In particular, each anchor region 416 has a first length L₁ extending along a first axial direction, and a second length L₂ extending along a second axial direction. The first and second directions may be normal or perpendicular to one another. The lengths L₁ and L₂ may also be equal. The lengths extending in two axial directions allow multiple spaced out package-mounting points 419 per anchor to provide table-like stability so that the interposer 410 avoids rocking or tilting during assembly and operation. This concept can be extended to include platforms with more than two L-shaped springs, for example, three, four, five, or more L-shaped legs. The device-mounting region 412 has cutout regions 418 into which the anchors extend, allowing the interposer to maintain a compact footprint with a simple rectangular or square geometry. In this embodiment, the cutout regions 418 are each “stair-stepped” shaped in that they extend in perpendicular axial directions in alternating fashion. This allows the anchor regions 416 to assume the L-shape. As the cutouts 418 extend further inward from the outer edge of the interposer 410, they finish in one linear direction (e.g., along the direction of L₁), and then turn inwardly (e.g., along the direction of L₂). The interposer can optionally be designed such that the entire interposer fits beneath the device being mounted.

This embodiment also exemplifies how the anchor regions 416 can be more inboard than portions of the device-mounting regions. For example, a first distance D₁ may be defined between a center point of the device-mounting region 412 and one of the springs, and a second distance D₂ may be defined between the center point of the device-mounting region 412 and the anchor region 416, and the second distance may be less than the first distance. Due to the L-shaped design of the anchor region 416 along with a width that exceeds that of the spring 414, a portion of the anchor region 416 is located closer to the center of the interposer than the springs. Most of the anchor region 416 may be located closer to the center than the spring 414 that connects the anchor region 416 to the device-mounting region 412 is.

Furthermore, the anchor regions 416 may be within an extended perimeter or virtual perimeter of the device-mounting region 412. The embodiment of FIG. 7A-7B shows a device-mounting region 412 that is not square-shaped. However, if one were to extend the stair-stepped shape of the perimeter of the device-mounting region such that it was square shaped (e.g., by extending the regions of the device-mounting region 412 in the first and third quadrants of the view of FIG. 7A to align with the furthest existing edges of the device-mounting region 412), it would be evident that part of the anchor regions 416 would be within this extended or virtual perimeter. This provides a compact interposer with anchor regions close to the center of the interposer.

### 5. Fifth Embodiment

See FIG. 8. An interposer platform 510, similar to the first embodiment, but with more than two springs or legs 514 (in this case four legs). Each leg 514 terminates in an individual anchor 516 that provides area for one or more mounting points 519 to attach the interposer to an underlying package or substrate. This geometry allows the interposer to maintain a compact footprint with a simple rectangular or square geometry. The device-mounting region 512 has cutout regions 518 that each have three linear regions, making orthogonal jogs as the cutout regions extend further into the platform 510. The interposer can optionally be designed such that the entire interposer fits beneath the device being mounted. Once again, the anchor regions 516 may be located within the extended profile of the device-mounting region 512. In other words, if the device-mounting region 512 were to have the corners of its perimeter extended outward such that the perimeter (shown in broken lines) were to be square-shaped, it would be evident that the anchor regions 516 are partially located within the extended perimeter. This once again provides a compact interposer design with a reduced surface profile.

### 6. Sixth Embodiment

See FIGS. 9A-9B. An interposer platform 610, similar to the fifth embodiment, but with springs or legs 614 extending inward toward the center of the platform through cutout regions 618 in the device-mounting region 612. Each cutout 618 first extends transverse to an outer edge of the platform 610, and then turns approximately 45 degrees toward the center of the platform. Each leg 614 terminates in an individual anchor 616 that provides area for one or more mounting points 619 to attach the interposer to an underlying package or substrate. This geometry allows the interposer to maintain a compact footprint with a simple rectangular or square geometry. The interposer can optionally be designed such that the entire interposer fits beneath the device being mounted.

### 7. Seventh Embodiment

See FIGS. 10A-10B. An interposer platform 710, similar to the fifth embodiment, but with multiple springs or legs 714 extending from each anchor 716 to support the mounting region. Two or more legs 714 terminate in an individual anchor 716 that provides area for one or more package-mounting points 719 to attach the interposer to an underlying package or substrate. The device-mounting region 712 is surrounded by cutouts 718 that each have four linear directions. This geometry allows the interposer to maintain a compact footprint with a simple rectangular or square geometry. The interposer can optionally be designed such that the entire interposer fits beneath the device being mounted.

### Additional Embodiments

The concepts disclosed can be extended to include interposers with any number of legs or springs, as well as interposers with multiple mounting regions. Although the specific embodiments illustrated show right-angle and rectangular geometry for the springs, anchors, mounting regions, and cut-out regions, the same concepts can be applied with curved geometry. This would include circular, elliptical, or oval mounting regions, and curved or rounded springs, anchors, and cut-out regions.

### II. Die Attach/Assembly.

For interposer platforms with the geometries described above, several options can be used to affix the device being mounted to the interposer mounting region and to affix the interposer anchors to the underlying package or substrate. These are illustrated in FIGS. 11A-C. As illustrated in FIG. 11A, die-attach adhesives 800 such as epoxies, cyanate esters, silicones, or other suitable adhesives can be used in the device-mounting region and in the package-mounting points or regions as defined in FIG. 4 through FIG. 10. Alternatively, if the backside (or underside) of the device and/or the interposer are coated with metal, the attachment can be accomplished by solder reflow. In this case, solder preforms 900 made from AuSn or another suitable alloy may be used to place solder at the appropriate locations on the device and platform, as illustrated in FIG. 11B. An additional alternative is to use thermocompression or thermosonic bonding to adhere the components to one another using metal stud bumps 1000, as illustrated in FIG. 11C. The device being mounted is affixed to the interposer's central region, and the interposer is affixed to the package at mounting points on the peripheral anchor regions.

An alternative configuration is illustrated in FIGS. 12A-B and FIG. 13, where the mounting regions are reversed; the device 30 is affixed to the interposer 110 at the peripheral anchor regions 116 and the interposer 110 is affixed to the underlying package or substrate at the central region of the platform 20. In other words, the anchor regions 116 provide mounting points 119 on the upper side of the interposer 110, while the device-mounting region 112 is on the underside of the interposer 110.

### III. Interposer Material.

The material from which the interposer platform is manufactured can be selected to have a coefficient of thermal expansion (CTE) that is well matched to the device being supported. For example, for a MEMS sensor substrate that is typically silicon or glass, the interposer can be made from silicon or glass respectively. (Since silicon and glass have a similar CTE, glass-based devices can also be mounted on silicon interposers, and silicon-based devices can also be mounted on glass interposers.) If a given application benefits from thermally isolating the device, the interposer can be made from a thermally-insulating material such as glass. If, alternatively, an application demands that the device be heat-sinked to the substrate below, the interposer can be made from a thermally-conductive material such as silicon. Other materials including ceramics, polymers, elastomers, or metals can be selected to obtain optimal mechanical and thermal characteristics.

### IV. Sensing and Actuating Features.

Several optional sensing and actuating features can be added to the interposer substrate to customize it for specific applications.

A. Temperature Control/Ovenization.

If temperature control of the device is desired, a heater made from thin-film metal, polysilicon, or other material can be patterned on the interposer platform. As well, the interposer can include an integrated thin-film temperature sensor, such as a resistive temperature device (RTD), made from metal, polysilicon, or other material. U.S. Pat. Nos. 8,049,326 and 8,698,292, which utilize temperature control, are hereby incorporated by reference in their entirety. Likewise, the interposer can incorporate a thermistor, or other semiconductor temperature sensing device. A discrete heater or temperature sensing device can also be mounted on the interposer alongside the device being isolated.

B. Strain Measurement.

Some applications may benefit from monitoring the mechanical strain on the interposer platform, to serve as an estimate of the strain experienced by the device mounted on the platform. In this case, the mounting region of the interposer can incorporate integrated strain sensors, such as serpentine thin-film metal, polysilicon, or other material strain gauges. Alternatively, one or more discrete strain sensing devices can be mounted on the platform alongside or beneath or above the device being isolated.

### V. Electrical Features.

Several optional electrical features can be added to the interposer substrate to customize it for particular applications.

A. Signal/Power Routing.

The interposer can include thin-film metal patterns for establishing electrical connections and routing power and signals to the device mounted on the interposer. Metal lands for wire-bonding can be included on the mounting region, wires can be patterned on the legs, and metal lands can be included on the anchors for wire-bonding to the underlying substrate or package. When the platform is thermally insulating, this can reduce thermal conduction that can occur through the wirebonds from the device to the outside world. FIGS. 14A-B illustrates this approach, as well as the contrasting approach where wirebonds connect directly from the package to the device. FIG. 14A shows a device 30 mounted on an interposer platform 10, with electrical connections established by wire-bonding directly from the device to pads on the package 20 or underlying substrate. FIG. 14B shows a device 30 mounted on an interposer platform 10, with electrical connections established by wire-bonding from the device to metal pads patterned on the interposer mounting region 16. Thin-film metal wires can carry the signals from these pads, across the platform legs, to a second set of pads on the interposer anchors. The anchor pads can then be connected to the package or underlying substrate with wire bonds.

B. Integrated Passive Components.

The interposer can also include one or more integrated passive electrical components such as resistors or capacitors patterned in metal and insulating layers on the surface of the interposer.

C. Pads for Surface-Mount Components.

The interposer can contain lands for epoxy- or solder-mounting electronic or electrical components on the interposer. (These would be peripheral components to support the operation of the primary device being isolated).

D. Through-Substrate Interconnects.

The interposer can include through-substrate electrical connections to carry electrical signals from the device to the bottom of the interposer. The interposer can include bottom-side pads on the anchors, which would allow the interposer to be flip-chip bonded directly to the package pads. (Through-substrate vias on the interposer would carry signals from the device on the top side to the pads on the bottom side.)

### VI. Package Type and Packaging Conditions.

The interposer can be assembled into an overall package design with several different embodiments and incorporating different features, for example:

A. Cavity Package.

The interposer can be mounted within a cavity package made, for example, from ceramic or plastic. The device can be mounted on the interposer, and a flat or dome lid can be installed on the package. This embodiment is illustrated in FIG. 2.

B. Planar Package with Dome Lid.

The interposer can be mounted on a substantially planar package substrate, for example made from a laminate material such as an FR-4 printed circuit board. Alternatively, the planar package substrate can be made from ceramic or another suitable material. The device can be mounted on the interposer, and a dome lid can be installed onto the package substrate, encapsulating the interposer and the device.

C. Planar Package with Spacer and Dome Lid.

The interposer can be mounted on a substantially planar package substrate, for example made from a laminate material such as an FR-4 printed circuit board. Alternatively, the planar package substrate can be made from ceramic or another suitable material. The device can be mounted on the interposer. A spacer or shim structure can be installed in a perimeter region, located vertically between the package substrate and a flat or dome lid, with the spacer or shim being used to provide a taller cavity within the package, to accommodate the height of the interposer, device, and wire bonds.

D. Vacuum or Hermetic Sealing.

The package cavity formed in the way described above can be sealed in vacuum, in air or an inert gas at ambient pressure, or in air or inert gas with a positive pressure. Sealing at vacuum can promote thermal isolation since gas conduction and convection are greatly reduced or eliminated when the package cavity is evacuated of gas species. Sealing at vacuum or with an inert gas can reduce or eliminate deleterious effects of humidity and variations in humidity. Sealing at vacuum can improve the performance of resonant devices such as MEMS resonators and gyroscopes. Sealing at ambient pressure or a positive pressure can promote damping mechanisms such as squeeze-film damping, which can be advantageous for some MEMS devices such as accelerometers. The package can incorporate a coating material such as gel or parylene to reduce effects from humidity variation and moisture ingress.

E. Heat Shield.

For a package with a heated platform where thermal isolation is paramount, the package can incorporate a heat shield to reduce thermal loss due to radiation. The heat shield can be mounted to the isolation substrate and be maintained at approximately the same temperature as the platform.

### VII. Device Type.

The interposer and package types above can be used to package numerous types of devices, for example:

A. Inertial Sensors.

The device can be inertial sensors such as MEMS gyroscopes and accelerometers, based on semiconductor technology or quartz. A single sensor or multiple sensors integrated together on a single chip can be mounted on an interposer in a package. Alternatively, multiple chips (dies) with one or more sensors can be combined on a single interposer or on multiple interposers in a single package. An integrated circuit such as an application-specific integrated circuit (ASIC) for reading out the inertial sensor(s) can be mounted with the sensor chips. Alternatively, the sensors can be integrated with circuits on the same chip, or the sensor chip can be bonded to a circuit chip. This bonded stack can be mounted to an interposer in a package with either the sensor die closest to the interposer or the circuit chip closest to the interposer.

B. Magnetic Field Sensors.

The device may be magnetic field sensing devices such as magnetometers. A single sensor or multiple sensors integrated together on a single chip can be mounted on an interposer in a package. Alternatively, multiple chips (dies) with one or more sensors can be combined on a single interposer or on multiple interposers in a single package. An integrated circuit such as an application-specific integrated circuit (ASIC) for reading out the manetometer(s) can be mounted with the sensor chips. Alternatively, the sensors can be integrated with circuits on the same chip, or the sensor chip can be bonded to a circuit chip. This bonded stack can be mounted to an interposer in a package with either the sensor chip closest to the interposer or the circuit chip closest to the interposer.

C. Pressure and Acoustic Transducers.

The device may be pressure transducing devices, such as piezoelectric or capacitive MEMS pressure sensors, as well as acoustic sensing/actuating devices such as microphones, speakers, and ultrasound transducers. In the case of the pressure sensors and acoustic devices, the package can be customized to allow pressure or acoustic access to the sensitive areas of the devices. A single transducer or multiple transducers integrated together on a single chip can be mounted on an interposer in a package. Alternatively, multiple chips (dies) with one or more transducers can be combined on a single interposer or on multiple interposers in a single package. An integrated circuit such as an application-specific integrated circuit (ASIC) for interfacing to the transducers can be mounted with the transducer chips. Alternatively, the transducers can be integrated with circuits on the same chip, or the transducer chip can be bonded to a circuit chip. This bonded stack can be mounted to an interposer in a package with either the transducer die closest to the interposer or the circuit chip closest to the interposer.

D. Optical Devices.

The device may be an optical sensing or actuating device, such as a CMOS image sensor, charge-coupled device, bolometer or other optical detector for light in the visible spectrum or invisible spectra. In the case of an optical device, the package can be customized with an appropriately transparent window to allow optical axis to the sensitive part of the device. A single sensor or multiple sensors integrated together on a single chip can be mounted on an interposer in a package. Alternatively, multiple chips (dies) with one or more sensors can be combined on a single interposer or on multiple interposers in a single package. An integrated circuit such as an application-specific integrated circuit (ASIC) for reading out and controlling the optical device(s) can be mounted with the sensor chips. Alternatively, the sensors can be integrated with circuits on the same chip, or the sensor chip can be bonded to a circuit chip. This bonded stack can be mounted to an interposer in a package with either the sensor die closest to the interposer or the circuit chip closest to the interposer.

E. Quartz Crystals.

The device may be quartz crystals for timing references such as crystal oscillators or for bulk-acoustic wave (BAW) or surface-acoustic wave (SAW) sensing devices. A single sensor or multiple sensors integrated together on a single chip can be mounted on an interposer in a package. Alternatively, multiple chips (dies) with one or more sensors can be combined on a single interposer or on multiple interposers in a single package. An integrated such as an application-specific integrated circuit (ASIC) or other circuit components for forming an oscillator can be mounted with the crystal.

F. Integrated Circuits.

The device may be integrated circuits such as analog or mixed-signal ASICs. One or more integrated circuits that can benefit from stress isolation or temperature stabilization can be mounted on an interposer in a package.

G. Combined Devices.

The device may be any combination of the above devices (integrated circuits, quartz crystals, optical devices, pressure or acoustic transducers, magnetometers, or inertial sensors) mounted on one or more interposers in a package.

H. Other Devices.

Any other single instance or combination of multiple sensors, actuators, or electronic devices that can benefit from stress isolation, vibration filtering, or temperature stabilization can be mounted on one or more interposers in a package.

While exemplary embodiments are described above, it is not intended that these embodiments describe all possible forms encompassed by the claims. The words used in the specification are words of description rather than limitation, and it is understood that various changes can be made without departing from the spirit and scope of the disclosure. As previously described, the features of various embodiments can be combined to form further embodiments of the invention that may not be explicitly described or illustrated. While various embodiments could have been described as providing advantages or being preferred over other embodiments or prior art implementations with respect to one or more desired characteristics, those of ordinary skill in the art recognize that one or more features or characteristics can be compromised to achieve desired overall system attributes, which depend on the specific application and implementation. These attributes can include, but are not limited to cost, strength, durability, life cycle cost, marketability, appearance, packaging, size, serviceability, weight, manufacturability, ease of assembly, etc. As such, to the extent any embodiments are described as less desirable than other embodiments or prior art implementations with respect to one or more characteristics, these embodiments are not outside the scope of the disclosure and can be desirable for particular applications.

It should also be reiterated that descriptions of certain embodiments can be combined with features of another embodiment. For example, the description regarding the location and features of the device-mounting regions, the gaps, and the anchor regions of FIGS. 4A-4B can be applied to other embodiments as well.

What is claimed is:

1. A planar interposer formed from a single planar layer of material, the planar interposer configured to isolate a device from mechanical stress, vibration or thermal variation, the planar interposer comprising:
a device-mounting region in the single planar layer of material and configured to mount to the MEMS device;
two or more legs formed out of the single planar layer of material, wherein the legs are configured to act as springs to isolate the device-mounting region from mechanical stress, vibration or thermal variation, each leg having a width; and
an anchor region at a terminal end of each of the legs and configured to mount to an underlying package or substrate, each anchor region spaced from the device-mounting region by a corresponding cut-out or gap, each cut-out or gap configured such that at least a portion of each anchor region is further inboard on the interposer than a portion of the device-mounting region.

2. The planar interposer of claim 1, wherein the at least a portion of each anchor region wraps around and nests within the portion of the device-mounting region.

3. The planar interposer of claim 1, wherein each anchor region has a first portion having a first length extending along a first axis, and a second portion have a second length extending along a second axis perpendicular to the first axis.

4. The planar interposer of claim 3, wherein the first portion has a first width that is wider than the width of the legs, and the second portion has a second width that is wider than the width of the legs.

5. The planar interposer of claim 1, wherein the gap has a stair-stepped shape.

6. The planar interposer of claim 5, wherein the gap has a first portion extending along a first axis, a second portion extending along a second axis perpendicular to the first axis, and a third axis extending parallel to the first axis.

7. The planar interposer of claim 1, wherein each anchor region being at least partially L-shaped and having a width that exceeds the width of the legs.

8. An interposer for isolating a MEMS device from its package, the interposer comprising:
a device-mounting region in the center of the interposer and configured to support the MEMS device;
a plurality of springs extending from the device-mounting region and configured to isolate the device-mounting region from mechanical stress, vibration or thermal variation, the springs separated from the device-mounting region by one or more gaps; and
an anchor region at a terminal end of each of the springs, each anchor region configured to mount to an underlying package or substrate;
wherein a first distance is defined between a center point of the device-mounting region and one of the springs, and a second distance is defined between the center point of the device-mounting region and the anchor region, wherein the second distance is less than the first distance.

9. The interposer of claim 8, wherein each anchor region is at least partially L-shaped and has a width that exceeds a width of the springs.

10. The interposer of claim 8, wherein the device-mounting region, the springs, and the anchor region are all defined by a single planar layer of material.

11. The interposer of claim 8, wherein the device-mounting region includes a plurality of edges, and each anchor region wraps around a corresponding one of the edges.

12. The interposer of claim 8, wherein each anchor region has a first portion having a first length extending along a first axis, and a second portion have a second length extending along a second axis perpendicular to the first axis.

13. The planar interposer of claim 12, wherein the first portion has a first width that is wider than a width of the legs, and the second portion has a second width that is wider than the width of the legs.

14. The planar interposer of claim 8, wherein the anchor region has an adhesive provided thereon that covers a majority of the anchor region.
